(19) United States
(12) Patent Application Publication
(10) Pub. No.: US 2025/0093780 A1
(43) Pub. Date: Mar. 20, 2025

(54) WATER SOLUBLE PROTECTIVE COATINGS FOR ENGINEERED OPTICAL DEVICES

(71) Applicant: Applied Materials, Inc., Santa Clara, CA (US)

(72) Inventors: Amit Kumar ROY, Mumbai (IN); Srobona SEN, Mumbai (IN); Kankona S. ROY, Bangalore (IN); Xiaopei DENG, San Jose, CA (US); Gopi Chandran Ramachandran, Mumbai (IN); Robert VISSER, Menlo Park, CA (US)

(21) Appl. No.: 18/885,477

(22) Filed: Sep. 13, 2024

(30) Foreign Application Priority Data
Sep. 14, 2023 (IN) 202341061848

(51) Int. Cl. G03F 7/11; G03F 7/16

(52) U.S. Cl. CPC G03F 7/11; G03F 7/162; G03F 7/168

(57) ABSTRACT

Embodiments of the present disclosure generally relate to optical devices, and more specifically, protective coatings for optical devices and methods for preparing protective coatings on optical devices and other devices. In one or more embodiments, a method for protecting a photoresist on a workpiece is provided and includes depositing a photoresist layer on a first surface of a substrate, and depositing a protective coating on the photoresist layer disposed on the first surface, wherein the protective coating contains a water-soluble polymeric material. Thereafter, the method includes exposing a second surface of the substrate to one or more fabrication processes, where the first surface is covered by the photoresist layer and the protective coating, and the second surface is uncovered. Thereafter, the method further includes removing the protective coating by at least partially dissolving the water-soluble polymeric material with a removal solution containing water or an aqueous solution.

### CROSS-REFERENCE TO RELATED APPLICATIONS

This application claims benefit to Indian Provisional Appl. No. 202341061848, filed on Sep. 14, 2023, which is herein incorporated by reference.

### BACKGROUND

### Field

Embodiments of the present disclosure generally relate to optical devices, and more specifically, coatings for optical devices and methods for preparing coatings on optical devices and other surfaces.

### Description of the Related Art

The fabrication of optical devices often requires multiple process steps. In the case of double-sided devices, there is a need to protect an underlying layer of the device or substrate while going through the subsequent process steps. Sacrificial coatings have been used as a temporary protective coating. However, these sacrificial coatings may require vacuum technology processes such as plasma ashing or dry etching for removing the sacrificial coatings. Unfortunately, plasma ashing and dry etching often causes damage to the underlying surfaces, especially on sensitive surfaces on optical devices. Also, plasma ashing and dry etching technologies pose significant challenges while scaling up for high-volume manufacturing, especially in the area of optical device fabrication and production.

Therefore, there is need for an improved method for protecting substrate surfaces, especially on optical devices, while conducting further fabrication processes.

### SUMMARY

Embodiments of the present disclosure generally relate to optical devices, and more specifically, protective coatings for optical devices and methods for preparing protective coatings on optical devices and other surfaces and devices.

In one or more embodiments, a method for protecting a photoresist on a workpiece is provided and includes depositing a photoresist layer on a first surface of a substrate, wherein the photoresist layer contains a poly(methyl methacrylate) (PMMA) or one or more other water-insoluble photoresist materials, and depositing a protective coating on the photoresist layer disposed on the first surface, wherein the protective coating contains a water-soluble polymeric material. Thereafter, the method includes exposing a second surface of the substrate to one or more fabrication processes, where the first surface is covered by the photoresist layer and the protective coating, and the second surface is uncovered. Thereafter, the method further includes removing the protective coating by at least partially dissolving the water-soluble polymeric material with a removal solution containing water, deionized water, an aqueous solution, isopropanol, methanol, ethanol, or any combination thereof.

In other embodiments, a method for protecting a photoresist on a workpiece is provided and includes depositing a photoresist layer on a substrate, wherein the photoresist layer may be or contain a PMMA, and depositing a protective coating on the photoresist layer. The protective coating contains a water-soluble polymeric material containing a polyvinyl pyrrolidone (PVP). Thereafter, the method includes exposing the workpiece to one or more fabrication processes, and then removing the protective coating by at least partially dissolving the water-soluble polymeric material with a removal solution containing water.

In some embodiments, a workpiece is provided and contains a photoresist layer disposed on a substrate, and a protective coating disposed on the photoresist layer. The photoresist layer contains a PMMA. The protective coating contains a water-soluble polymeric material, where the water-soluble polymeric material may be or contain a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

### BRIEF DESCRIPTION OF THE DRAWINGS

So that the manner in which the above recited features of the present disclosure may be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a cross-sectional view of a workpiece having a photoresist layer disposed on a substrate, and a protective coating disposed on the photoresist layer, according to one or more embodiments described and discussed herein.

FIG. 2 is a flowchart illustrating a method for protecting a photoresist on a workpiece, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to optical devices, and more specifically, coatings for optical devices and methods for preparing the coatings and processing the optical devices.

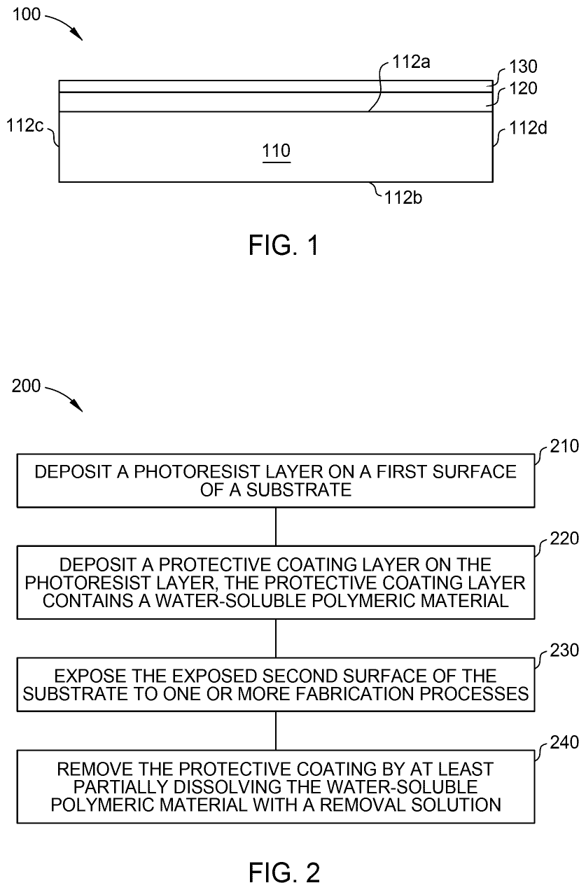

FIG. 1 depicts a cross-sectional view of a workpiece 100 having a photoresist layer 120 deposited, formed, produced, or otherwise disposed on a substrate 110, and a protective coating 130 deposited, formed, produced, or otherwise disposed on the photoresist layer 120, according to one or more embodiments described and discussed herein. The substrate 110 may have multiple surfaces 112a-112d. In one or more embodiments, the photoresist layer 120 and the protective coating 130 are on the surface 112a while the other surfaces 112b-112d are exposed during processing and/or fabrication steps, as shown in FIG. 1. In other embodiments, not shown, the photoresist layer 120 and the protective coating 130 are on any one, two, or three of the surfaces 112a-112d, while one, two, or three of the remaining surfaces 112a-112d are left exposed during processing and/or fabrication steps.

In one or more embodiments, the substrate 110 may be a device or a portion of the device selected from one or more of optical devices, waveguide combiners, flexible displays, other devices, or any combination thereof. In one or more examples, the substrate 110 may be or include, comprises, or consist essentially of silicon, doped-silicon, silicon germanium, or other elements.

FIG. 2 is a flowchart illustrating a method or process 200 for protecting the photoresist layer 120 disposed on the substrate 110 within the workpiece 100, according to one or more embodiments described and discussed herein. The process 200 may include operations 210-240, as shown in FIG. 2. The process 200 may be used with the workpiece 100, as described and discussed herein, but may also be used in a variety of other workpieces, which include substrates, wafers, optical devices, flexible displays, waveguide combiners, other devices, and/or other materials used in microelectronic technologies, optics technologies, battery technologies, and other technologies.

In one or more embodiments, the process 200 for protecting the photoresist or other intermediate layer on the workpiece 100 is provided and includes depositing the photoresist layer 120 on a first surface 112a of the substrate 110 while maintaining at least one of the surfaces 112b-112d free or substantially free of the photoresist layer 120, during operation 210 of the process 200. In other examples, the photoresist layer 120 may be deposited on one, two, or three of the surfaces 112a-112d while maintaining one, two, or three of the surfaces 112b-112d free or substantially free of the photoresist layer 120.

The photoresist layer 120 may be, include, or contain one or more polymers, oligomers, resins, or any combination thereof, suitable to be used as a photoresist material. In one or more examples, the photoresist layer 120 may be, include, or contain one or more organic-containing material or layer which is insoluble in water or an aqueous solution. Exemplary materials for the photoresist layer 120 may be or contain a poly(methyl methacrylate) (PMMA), one or more other water-insoluble photoresist materials, or any combination thereof. In some examples, the photoresist layer 120 may be or contain an organometallic oxide photoresist material (e.g., organotin oxide). In other embodiments, the photoresist layer 120 may include an intermediate layer or other type of layer which is not a photoresist layer or does not contain a photoresist material.

The photoresist layer 120 may be deposited, formed, produced, or otherwise disposed on the substrate 110 by one or more wet deposition processes and/or one or more dry deposition processes. In one or more examples, the photoresist layer 120 is deposited on the substrate 110 by a spin-coating process. In other examples, the photoresist layer 120 is deposited on the substrate 110 by other wet deposition processes. In some examples, the photoresist layer 120 is deposited on the substrate 110 by one or more dry deposition processes, such as a chemical vapor deposition (CVD) process or an atomic layer deposition (ALD) process.

In one or more embodiments, the photoresist layer 120 may have a thickness in a range from about 20 nm, about 50 nm, about 80 nm, about 100 nm, about 150 nm, about 200 nm or about 300 nm to about 400 nm, about 500 nm, about 600 nm, about 800 nm, about 1,000 nm, about 1,200 nm, about 1,500 nm, about 1,800 nm, about 2,000 nm, or greater. For example, the photoresist layer 120 may have a thickness in a range from about 20 nm to about 2,000 nm, about 100 nm to about 2,000 nm, about 100 nm to about 1,500 nm, about 100 nm to about 1,200 nm, about 100 nm to about 1,000 nm, about 100 nm to about 800 nm, about 100 nm to about 600 nm, about 100 nm to about 500 nm, about 100 nm to about 400 nm, about 100 nm to about 350 nm, about 100 nm to about 300 nm, about 100 nm to about 250 nm, about 100 nm to about 200 nm, about 100 nm to about 150 nm, about 200 nm to about 2,000 nm, about 200 nm to about 1,500 nm, about 200 nm to about 1,200 nm, about 200 nm to about 1,000 nm, about 200 nm to about 800 nm, about 200 nm to about 600 nm, about 200 nm to about 500 nm, about 200 nm to about 400 nm, about 200 nm to about 350 nm, about 200 nm to about 300 nm, about 200 nm to about 250 nm, about 500 nm to about 2,000 nm, about 500 nm to about 1,500 nm, about 500 nm to about 1,200 nm, about 500 nm to about 1,000 nm, about 500 nm to about 800 nm, or about 500 nm to about 600 nm.

In one or more examples, the photoresist layer 120 may have a thickness in a range from about 20 nm to about 2,000 nm. In other examples, the photoresist layer 120 may have a thickness in a range from about 100 nm to about 800 nm. In some examples, the photoresist layer 120 has a thickness in a range from about 200 nm to about 400 nm.

During operation 220 of the process 200, the protective coating 130 may be deposited, formed, produced, or otherwise disposed on the photoresist layer 120 which is disposed on any one, two, or three surfaces 112a-112d of the substrate 110. In one or more examples, the protective coating 130 may be deposited, formed, produced, or otherwise disposed on the photoresist layer 120 which is disposed on the surface 112a, while the surfaces 112b-112d of the substrate 110 are left exposed, as shown in FIG. 1. In other examples, the protective coating 130 may be deposited, formed, produced, or otherwise disposed on the photoresist layer 120 which is disposed on any one, two, or three surfaces 112a-112d of the substrate 110, while the remaining surfaces 112b-112d of the substrate 110 are left exposed (not shown).

The protective coating 130 contains one or more water-soluble polymeric materials, one or more water-soluble oligomeric materials, one or more water-soluble resin materials, or any combination thereof. Exemplary water-soluble polymeric material may be or contain a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

In one or more embodiments, the water-soluble polymeric material has an average molecular weight (MW) in a range from about 1 kDa, about 2 kDa, about 2.5 kDa, about 3 kDa, about 5 kDa, about 8 kDa, about 10 kDa, about 20 kDa, about 35 kDa, about 50 kDa, or about 80 kDa to about 100 kDa, about 120 kDa, about 150 kDa, about 200 kDa, about 250 kDa, about 300 kDa, about 500 kDa, about 800 kDa, about 1,000 kDa, about 1,200 kDa, about 1,500 kDa, about 2,000 kDa, about 3,000 kDa, about 5,000 kDa, or greater. For example, the water-soluble polymeric material has an average MW in a range from about 1 kDa to about 5,000 kDa, about 1 kDa to about 3,000 kDa, about 1 kDa to about 2,000 kDa, about 1 kDa to about 1,500 kDa, about 1 kDa to about 1,000 kDa, about 1 kDa to about 800 kDa, about 1 kDa to about 600 kDa, about 1 kDa to about 500 kDa, about 1 kDa to about 400 kDa, about 1 kDa to about 200 kDa, about 1 kDa to about 100 kDa, about 1 kDa to about 80 kDa, about 1 kDa to about 50 kDa, about 1 kDa to about 20 kDa, about 20 kDa to about 5,000 kDa, about 20 kDa to about 3,000 kDa, about 20 kDa to about 2,000 kDa, about 20 kDa to about 1,500 kDa, about 20 kDa to about 1,000 kDa, about 20 kDa to about 800 kDa, about 20 kDa to about 600 kDa, about 20 kDa to about 500 kDa, about 20 kDa to about 400 kDa, about 20 kDa to about 200 kDa, about 20 kDa to about 100 kDa, about 20 kDa to about 80 kDa, about 20 kDa to about 50 kDa, about 100 kDa to about 5,000 kDa, about 100 kDa to about 3,000 kDa, about 100 kDa to about 2,000 kDa, about 100 kDa to about 1,500 kDa, about 100 kDa to about 1,000 kDa, about 100 kDa to about 800 kDa, about 100 kDa to about 600 kDa, about 100 kDa to about 500 kDa, about 100 kDa to about 400 kDa, about 100 kDa to about 200 kDa, about 100 kDa to about 150 kDa, about 1,000 kDa to about 5,000 kDa, about 1,000 kDa to about 4,000 kDa, about 1,000 kDa to about 3,000 kDa, about 1,000 kDa to about 2,500 kDa, about 1,000 kDa to about 2,000 kDa, or about 1,000 kDa to about 1,500 kDa.

In some examples, the water-soluble polymeric material may be or contain a polyvinyl pyrrolidone (PVP). In one or more examples, the PVP may have an average MW from about 10 kDa to about 500 kDa, about 15 kDa to about 200 kDa, or about 20 kDa to about 100 kDa. In some examples, the PVP may have an average MW of about 2.5 kDa to about 1,500 kDa, about 20 kDa to about 500 kDa, or about 20 kDa to about 100 kDa, such as about 40 kDa or such as about 300 kDa.

In one or more examples, the PAM may have an average MW in a range from about 1 kDa to about 600 kDa, or about 20 kDa to about 500 kDa, such as about 100 kDa. In one or more examples, the PVA may have an average MW of about 10 kDa to about 98 kDa, or about 89 kDa to about 98 kDa, such as about 94 kDa. In one or more examples, the PAA may have an average MW of about 8 kDa to about 450 kDa, or about 200 kDa to about 400 kDa, such as about 350 kDa.

The protective coating 130 may be deposited, formed, produced, or otherwise disposed on the photoresist layer 120 by one or more wet deposition processes and/or one or more dry deposition processes. In one or more examples, the protective coating 130 is deposited on the photoresist layer 120 by a spin-coating process. In other examples, the protective coating 130 is deposited on the photoresist layer 120 by other wet deposition processes. In some examples, the protective coating 130 is deposited on the photoresist layer 120 by one or more dry deposition processes, such as a CVD process or an ALD process.

In one or more examples, the water-soluble polymeric material is PVP and the protective coating 130 is spin coated onto the photoresist layer 120 from a deposition solution containing about 10 wt % of PVP. Thereafter, the spun film containing the PVP is heated at about 120° C. for about 30 min to form the protective coating 130 with a thickness in a range from about 205 nm to about 350 nm.

In one or more embodiments, the protective coating 130 may have a thickness in a range from about 20 nm, about 50 nm, about 80 nm, about 100 nm, about 150 nm, about 200 nm, about 205 nm, about 220 nm, about 250 nm, about 280 nm, or about 300 nm to about 320 nm, about 350 nm, about 380 nm, about 400 nm, about 500 nm, about 600 nm, about 700 nm, about 800 nm, about 1,000 nm, about 1,200 nm, about 1,500 nm, about 1,800 nm, about 2,000 nm, about 2,200 nm, about 2,500 nm, or greater. For example, the protective coating 130 may have a thickness in a range from about 20 nm to about 2,500 nm, about 20 nm to about 2,000 nm, about 100 nm to about 2,000 nm, about 100 nm to about 1,500 nm, about 100 nm to about 1,200 nm, about 100 nm to about 1,000 nm, about 100 nm to about 800 nm, about 100 nm to about 600 nm, about 100 nm to about 500 nm, about 100 nm to about 400 nm, about 100 nm to about 350 nm, about 100 nm to about 300 nm, about 100 nm to about 250 nm, about 100 nm to about 200 nm, about 100 nm to about 150 nm, about 250 nm to about 2,000 nm, about 250 nm to about 1,500 nm, about 250 nm to about 1,200 nm, about 250 nm to about 1,000 nm, about 250 nm to about 800 nm, about 250 nm to about 700 nm, about 250 nm to about 600 nm, about 250 nm to about 500 nm, about 250 nm to about 400 nm, about 250 nm to about 350 nm, about 250 nm to about 300 nm, about 500 nm to about 2,000 nm, about 500 nm to about 1,500 nm, about 500 nm to about 1,200 nm, about 500 nm to about 1,000 nm, about 500 nm to about 800 nm, or about 500 nm to about 600 nm.

In one or more examples, the protective coating 130 has a thickness in a range from about 20 nm to about 2,500 nm. In other examples, the protective coating 130 has a thickness in a range from about 100 nm to about 1,000 nm. In some examples, the protective coating 130 has a thickness in a range from about 250 nm to about 700 nm.

In one or more examples, the photoresist layer 120 may have a thickness in a range from about 20 nm to about 2,000 nm and the protective coating 130 has a thickness in a range from about 20 nm to about 2,500 nm. In other examples, the photoresist layer 120 may have a thickness in a range from about 100 nm to about 800 nm and the protective coating 130 has a thickness in a range from about 100 nm to about 1,000 nm. In some examples, the photoresist layer 120 has a thickness in a range from about 200 nm to about 400 nm and the protective coating 130 has a thickness in a range from about 250 nm to about 700 nm.

During operation 230 of the process 200, workpiece 100 containing the protective coating 130 is exposed to one or more fabrication processes. In one or more embodiments, as such, the exposed surfaces, the second surface 112b-112d of the substrate 110 (as shown in FIG. 1) are exposed to one or more fabrication processes, while the unexposed surfaces, the first surface 112a, remains covered by the photoresist layer 120 and the protective coating 130. Therefore, the one or more second surfaces 112b-112d, which are exposed or otherwise uncovered or unprotected, are subjected to the one or more fabrication processes. Exemplary fabrication processes may be or include exposing the second or exposed surfaces to one or more deposition processes, one or more etch processes, one or more cleaning processes, one or more curing processes, one or more thermal processes, one or more plasma processes, one or more other processes, or any combination thereof. The one or more fabrication processes are provided to advance the fabrication of the workpiece 100 during the overall manufacturing process of the product.

In one or more embodiments, the workpiece 100 containing at least the substrate 110, the photoresist layer 120, and the protective coating 130 may be heated during a curing process or other fabrication process. In one or more examples, the curing process or other fabrication process may include heating the workpiece 100 to a temperature in a range from about 80° C. to about 150° C. for about 1 minute to about 30 minutes prior to removing the protective coating 130. In other examples, the curing process or other fabrication process may include heating the workpiece 100 to a temperature in a range from about 100° C. to about 140° C. for about 2 minutes to about 20 minutes. In some examples, the curing process or other fabrication process may include heating the workpiece 100 to a temperature in a range from about 110° C. to about 130° C. for about 5 minutes to about 15 minutes. During the curing process or other fabrication process, the workpiece 100 may be under vacuum or under an atmosphere containing one or more inert gases (e.g., N₂, Ar, He, or any combination thereof.)

During operation 240 of the process 200, the workpiece 100 containing the protective coating 130 is exposed to one or more processes to remove the protective coating 130. For example, the protective coating 130 and/or the water-soluble polymeric material of the protective coating 130 may be at least partially dissolved or removed, substantially dissolved or removed, or completely dissolved or removed during operation 240. The workpiece 100 may be exposed one or more solvents or one or more solutions during one or more processes to remove the protective coating 130. In one or more examples, the protective coating 130 and/or the water-soluble polymeric material is exposed to one or more removal solutions containing water, deionized water, an aqueous solution, isopropanol, methanol, ethanol, acetone, acetonitrile, dimethylformamide (DMF), dimethyl sulfoxide (DMSO), one or more polar solvents, or any combination thereof. In one or more examples, the removal solution contains, comprises, consists essentially of, or consists of water, deionized water, or an aqueous solution. In some examples, the aqueous solution contains water and at least polar organic solvent. For example, the aqueous solution contains water and one or more alcohols, such as isopropanol, methanol, ethanol, or any combination thereof.

In one or more examples, the protective coating 130 is dissolved or otherwise removed from the photoresist layer 120 during a removal process. The removal process may include exposing the protective coating 130 to sonication within the removal solution. In other examples, the removal process exposes the protective coating 130 to the removal solution without sonication.

The removal solution may be heated to a temperature in a range from about 20° C., about 23° C., about 25° C., about 30° C., about 35° C., about 40° C., about 50° C., about 60° C., about 70° C., about 80° C., about 90° C., about 100° C., about 110° C., about 120° C., about 130° C., about 140° C., about 150° C., about 180° C., about 200° C., or greater during the removal process. For example, the removal solution may be heated to a temperature in a range from about 20° C. to about 200° C., about 20° C. to about 180° C., about 20° C. to about 150° C., about 20° C. to about 130° C., about 20° C. to about 120° C., about 20° C. to about 100° C., about 20° C. to about 150° C., about 20° C. to about 90° C., about 20° C. to about 80° C., about 20° C. to about 60° C., about 20° C. to about 50° C., about 20° C. to about 40° C., about 20° C. to about 35° C., about 20° C. to about 30° C., about 20° C. to about 25° C., about 35° C. to about 200° C., about 35° C. to about 180° C., about 35° C. to about 150° C., about 35° C. to about 130° C., about 35° C. to about 120° C., about 35° C. to about 100° C., about 35° C. to about 150° C., about 35° C. to about 90° C., about 35° C. to about 80° C., about 35° C. to about 60° C., about 35° C. to about 50° C., about 35° C. to about 40° C., about 50° C. to about 200° C., about 50° C. to about 180° C., about 50° C. to about 150° C., about 50° C. to about 130° C., about 50° C. to about 120° C., about 50° C. to about 100° C., about 50° C. to about 150° C., about 50° C. to about 90° C., about 50° C. to about 80° C., or about 50° C. to about 60° C. during the removal process.

The workpiece 100 containing the protective coating 130 may be exposed to the removal solution for a time period of about 0.5 min, about 1 min, about 1.5 min, about 2 min, about 3 min, about 4 min, about 5 min, about 6 min, or about 7 min to about 8 min, about 9 min, about 10 min, about 11 min, about 12 min, about 15 min, about 18 min, about 20 min, about 25 min, about 30 min, or longer during the removal process. For example, the workpiece 100 containing the protective coating 130 may be exposed to the removal solution for a time period of about 0.5 min to about 30 min, about 3 min to about 30 min, about 5 min to about 30 min, about 10 min to about 30 min, about 15 min to about 30 min, about 20 min to about 30 min, about 1 min to about 20 min, about 1.5 min to about 20 min, about 2 min to about 20 min, about 3 min to about 20 min, about 5 min to about 20 min, about 6 min to about 20 min, about 8 min to about 20 min, about 10 min to about 20 min, about 12 min to about 20 min, about 15 min to about 20 min, about 1 min to about 12 min, about 1.5 min to about 12 min, about 2 min to about 12 min, about 3 min to about 12 min, about 5 min to about 12 min, about 6 min to about 12 min, about 8 min to about 12 min, about 10 min to about 12 min, about 1 min to about 10 min, about 1.5 min to about 10 min, about 2 min to about 10 min, about 3 min to about 10 min, about 5 min to about 10 min, about 6 min to about 10 min, about 8 min to about 10 min, about 1 min to about 8 min, about 1.5 min to about 8 min, about 2 min to about 8 min, about 3 min to about 8 min, about 5 min to about 8 min, or about 6 min to about 8 min during the removal process.

In one or more examples, the removal solution may be heated to a temperature in a range from about 20° C. to about 150° C. for about 1 minute to about 12 minutes while at least partially dissolving the water-soluble polymeric material. In other examples, the removal solution may be heated to a temperature in a range from about 35° C. to about 130° C. for about 1.5 minutes to about 10 minutes while at least partially dissolving the water-soluble polymeric material. In some examples, the removal solution may be heated to a temperature in a range from about 50° C. to about 120° C. for about 2 minutes to about 8 minutes while at least partially dissolving the water-soluble polymeric material.

In one or more embodiments, a method for protecting a photoresist on a workpiece is provided and includes depositing a photoresist layer on one or more first surfaces of a substrate, wherein the photoresist layer contains a poly(methyl methacrylate) (PMMA), one or more other water-insoluble photoresist materials, or any combination thereof, and depositing a protective coating on the photoresist layer disposed on the one or more first surfaces, wherein the protective coating contains one or more water-soluble polymeric materials. Thereafter, the method includes exposing one or more second surfaces of the substrate to one or more fabrication processes, where the one or more first surface are covered by the photoresist layer and the protective coating, and the one or more second surfaces are exposed (e.g., not covered or protected by the protective coating). Thereafter, the method further includes removing the protective coating by at least partially dissolving the water-soluble polymeric material with a removal solution comprising water, deionized water, an aqueous solution, isopropanol, methanol, ethanol, or any combination thereof.

In some embodiments, a method for protecting a photoresist on a workpiece is provided and includes depositing a photoresist layer on a substrate, wherein the photoresist layer contains a PMMA, and depositing a protective coating on the photoresist layer, wherein the protective coating contains a water-soluble polymeric material comprising a polyvinyl pyrrolidone (PVP). In one or more examples, the PVP has an average molecular weight (MW) from about 20 kDa to about 100 kDa. Thereafter, the method includes exposing the workpiece to one or more fabrication processes, and then removing the protective coating by at least partially dissolving the water-soluble polymeric material with a removal solution comprising water. In some examples, the substrate comprises one or more first surfaces and one or more second surfaces, wherein the protective coating is disposed on the photoresist layer which is disposed on the one or more first surfaces of the substrate, and wherein the one or more fabrication processes comprise exposing the one or more second surfaces to one or more deposition processes, one or more etch processes, one or more cleaning processes, one or more curing processes, one or more thermal processes, one or more other processes, or any combination thereof.

In one or more embodiments, a workpiece is provided and contains a photoresist layer disposed on a substrate, and a protective coating disposed on the photoresist layer. The photoresist layer contains a PMMA. The protective coating contains a water-soluble polymeric material, where the water-soluble polymeric material may be or contain a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof. The water-soluble polymeric material may have an average MW from about 1 kDa to about 1,500 kDa. The water-soluble polymeric material may be or contain the polyvinyl pyrrolidone (PVP). The PVP may have an average MW from about 20 kDa to about 100 kDa. In some examples, the photoresist layer has a thickness in a range from about 100 nm to about 800 nm and the protective coating has a thickness in a range from about 100 nm to about 1,000 nm. The substrate may contain, comprises, consists of, or consist essentially of silicon.

In one or more embodiments, a workpiece is provided and contains a substrate, a water-soluble polymeric material, an intermediate layer (e.g., photoresist layer), the layers and/or the components as described and discussed herein. In other embodiments, a workpiece is provided and contains a water-soluble polymeric material deposited or disposed directly on or over a substrate without an intermediate layer (e.g., photoresist layer). In some embodiments, a workpiece is provided and contains a water-soluble polymeric material deposited or disposed on or over an intermediate layer (e.g., photoresist layer) which is deposited or disposed on or over a substrate. In other embodiments, the water-soluble polymeric material comprises a poly(acrylamide) (PAM) material, a polyvinyl pyrrolidone (PVP) material, a polyvinyl alcohol (PVA) material, a poly(acrylic acid) (PAA) material, salts thereof, derivatives thereof, or any combination thereof.

In one or more embodiments, a method is provided and includes depositing a water-soluble polymeric material directly on or over a substrate without an intermediate layer (e.g., photoresist layer). In other embodiments, a method is provided and includes depositing an intermediate layer (e.g., photoresist layer) on or over a substrate and depositing a water-soluble polymeric material on or over the intermediate layer (e.g., photoresist layer). In one or more embodiments, a method is provided and includes exposing the water-soluble polymeric material to one or more of water, deionized water, an aqueous solution, and/or other solvents to at least partially dissolve and/or remove the water-soluble polymeric material from the workpiece, such as the substrate and/or the intermediate layer.

In one or more embodiments, an easily removable sacrificial protective coating for optical devices is provided and maintains the integrity of the underlying polymer photoresist layer on devices especially during multi-step fabrication process flow. In some examples, water-soluble polymers for coating may be completely and efficiently removed by using environmentally friendly solvents, such as water and other aqueous solutions. The coatings provide sufficient mechanical protection and may be spin-coated on the devices. In other examples, commercially available, water-soluble polymers, such as polyvinyl pyrrolidone, have been deposited or otherwise disposed on optical devices. Also provided is a cost-effective environment-friendly technique for removing these coatings from the optical device.

In some examples, the method includes a solution for polymer-based water-soluble protective coatings which: 1. may be deposited via cost-effective technology like spin-coating using water or mild alcohol as the solvent medium; 2. may be cured at a relatively lower temperature (e.g., about 150° C. or less, such as about 20° C. to about 120° C.); 3. provide necessary mechanical protection to the optical device; 4. may be easily removed via sonication or dipping in water or an aqueous solution for about 10 minutes or less; and 5. may be scaled up for high-volume manufacturing since eco-friendly chemicals are used in the processes.

In one or more embodiments, metasurface-based flat optical devices and waveguide combiners have emerged as a new growth opportunity in the fields of display and smartphone market. The fabrication of the double-sided devices often involves sequential process steps done on each side which requires the backside protection using an easily removable protective layer. Embodiments provide that instead of organic-soluble polymers which needs harsh chemicals for the removal process, exemplary methods include commercially available water-soluble polymers. These polymers may be uniformly coated on the substrates via spin coating and easily removed without leaving any residue by sonicating in water (e.g., deionized water) and/or one or more aqueous solutions. These are optically transparent and have moderate mechanical strength. The mild conditions required for the removal process also maintains the performance integrity of the devices.

In one or more embodiments, five water-soluble polymers were chosen from a large pool of commercially available ones by virtue of their solubility in water, glass transition temperature and spin-coatability. These polymers may be spin coated on both blank as well as PMMA-coated Si substrates (about 3,000 rpm) and cured under the specified conditions. The film thickness may be modified by modulating the solution concentration and spin speed. The films spread well over the PMMA-coated surfaces indicating that they are well-suited for protecting the photoresist layers on the actual devices. In one or more examples, a polyvinyl pyrrolidone (PVP) material proved to form effective coating. The PVP films could be selectively removed by dipping into DI water. The PVP films are removed in water or aqueous solution at room temperature or greater, such as about 20° C., about 23° C., about 25° C. and greater temperatures (e.g., about 20° C. to about 120° C.). Sonication in DI water for 5 min ensures the complete removal of the film as shown via SEM without affecting the PMMA layer underneath.

The protective coatings (e.g., deposited WSPP films) disposed on blank and polymer-coated wafers or substrates may be characterized by the following methods/instruments: Thickness: Ellipsometry, SEM; Film quality: XPS, FTIR; Film modulus: DMA, Scratch Test.

Apart from the flat optical devices, these materials may also be used for encapsulation purposes in flexible displays, waveguide combiners, and other optical devices.

Embodiments of the present disclosure further relate to any one or more of the following Examples 1-46:

1. A workpiece, comprising a substrate, a water-soluble polymeric material, an intermediate layer (e.g., photoresist layer), the layers and/or the components as described and discussed herein.

2. A workpiece, comprising a water-soluble polymeric material deposited or disposed on or over a substrate.

3. A workpiece, comprising a water-soluble polymeric material deposited or disposed on or over an intermediate layer (e.g., photoresist layer) which is deposited or disposed on or over a substrate.

4. The workpiece according to any one of Examples 1-3, wherein the substrate comprises, consists of, or consist essentially of silicon.

5. The workpiece according to any one of Examples 1-4, wherein the intermediate layer (e.g., photoresist layer) comprises poly(methyl methacrylate) (PMMA).

6. The workpiece according to any one of Examples 1-5, wherein the water-soluble polymeric material comprises a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

7. The workpiece according to any one of Examples 1-6, wherein the water-soluble polymeric material has an average molecular weight (MW) from about 1 kDa to about 1,500 kDa.

8. A method, comprising a substrate, a water-soluble polymeric material, an intermediate layer (e.g., photoresist layer), the procedures, and/or the processes described and discussed herein.

9. A method, comprising depositing a water-soluble polymeric material on or over a substrate.

10. A method, comprising: depositing an intermediate layer (e.g., photoresist layer) on or over a substrate; depositing a water-soluble polymeric material on or over the intermediate layer.

11. The method according to any one of Examples 8-10, wherein the substrate comprises, consists of, or consist essentially of silicon.

12. The method according to any one of Examples 8-11, wherein the intermediate layer comprises poly(methyl methacrylate) (PMMA).

13. The method according to any one of Examples 8-12, wherein the water-soluble polymeric material comprises a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

14. The method according to any one of Examples 8-13, wherein the water-soluble polymeric material has an average molecular weight (MW) from about 1 kDa to about 1,500 kDa.

15. The method according to any one of Examples 8-14, wherein each of the intermediate layer and/or the water-soluble polymeric material is deposited by a spin-coating process.

16. The method according to any one of Examples 8-15, wherein a workpiece comprising at least the substrate, the water-soluble polymeric material, and optionally of the intermediate layer is heated to a temperature of about 80° C. to about 150° C., such as about 110° C. to about 130° C., or about 120° C. for about 1 minute to about 30 minutes, such as about 5 minutes to about 15 minutes, or about 10 minutes.

17. The method according to any one of Examples 8-16, wherein the workpiece and/or the water-soluble polymeric material is exposed to further processing.

18. The method according to any one of Examples 8-17, wherein the water-soluble polymeric material is removed from the substrate and/or the intermediate layer after a further processing procedure.

19. The method according to any one of Examples 8-18, wherein the water-soluble polymeric material is removed by exposing and at least partially dissolving the water-soluble polymeric material with water, deionized water, an aqueous solution, or other solvent.

20. A workpiece fabricated, produced, or otherwise made by the method according to any one of Examples 8-19 and/or a method to fabricate, produce, or otherwise make the workpiece according to any one of Examples 1-19.

21. A method for protecting a photoresist on a workpiece, comprising: depositing a photoresist layer on a first surface of a substrate, wherein the photoresist layer comprises a poly(methyl methacrylate) (PMMA), one or more other water-insoluble photoresist materials, or any combination thereof; depositing a protective coating on the photoresist layer disposed on the first surface, wherein the protective coating comprises a water-soluble polymeric material; then exposing a second surface of the substrate to one or more fabrication processes, wherein the first surface is covered by the photoresist layer and the protective coating, and the second surface is uncovered; then removing the protective coating by at least partially dissolving the water-soluble polymeric material with a removal solution comprising water, deionized water, an aqueous solution, isopropanol, methanol, ethanol, or any combination thereof.

22. The method according to Example 21, wherein the water-soluble polymeric material comprises a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

23. The method according Example 21 or 22, wherein the water-soluble polymeric material has an average molecular weight (MW) from about 1 kDa to about 1,500 kDa.

24. The method according to any one of Examples 21-23, wherein the water-soluble polymeric material comprises a polyvinyl pyrrolidone (PVP).

25. The method according to any one of Examples 21-24, wherein the PVP has an average molecular weight (MW) from about 20 kDa to about 100 kDa.

26. The method according to any one of Examples 21-25, wherein the water-soluble polymeric material is deposited on the photoresist layer by a spin-coating process to produce the protective coating.

27. The method according to any one of Examples 21-26, wherein the photoresist layer is deposited on the substrate by a spin-coating process.

28. The method according to any one of Examples 21-27, wherein the workpiece comprising at least the substrate, the photoresist layer, and the protective coating is heated during a curing process to a temperature in a range from about 80° C. to about 150° C. for about 1 minute to about 30 minutes prior to removing the protective coating.

29. The method according to any one of Examples 21-28, wherein the workpiece comprising at least the substrate, the photoresist layer, and the protective coating is heated during a curing process to a temperature is in a range from about 110° C. to about 130° C. for about 5 minutes to about 15 minutes.

30. The method according to any one of Examples 21-29, wherein the protective coating is removed from the photoresist layer during a removal process, the removal process comprises exposing the protective coating to sonication and the removal solution at a temperature in a range from about 20° C. to about 150° C. for about 1 minute to about 12 minutes while at least partially dissolving the water-soluble polymeric material, for examples, the temperature is in a range from about 50° C. to about 120° C. for a duration in a range from about 2 minutes to about 8 minutes.

31. The method according to any one of Examples 21-30, wherein the removal solution consists essentially of water or deionized water.

32. The method according to any one of Examples 21-31, wherein the substrate comprises or consist essentially of silicon.

33. The method according to any one of Examples 21-32, wherein the workpiece is at least a portion of an optical device selected waveguide combiners, flexible displays, and/or other devices.

34. The method according to any one of Examples 21-33, wherein the one or more fabrication processes comprise exposing the second surface to a deposition process, an etch process, a cleaning process, a curing process, a thermal process, one or more other processes, or any combination thereof.

35. The method according to any one of Examples 21-34, wherein the photoresist layer has a thickness in a range from about 100 nm to about 800 nm and the protective coating has a thickness in a range from about 100 nm to about 1,000 nm.

36. The method according to any one of Examples 21-35, wherein the photoresist layer has a thickness in a range from about 200 nm to about 400 nm and the protective coating has a thickness in a range from about 250 nm to about 700 nm.

37. A method for protecting a photoresist on a workpiece, comprising: depositing a photoresist layer on a substrate, wherein the photoresist layer comprises a poly(methyl methacrylate) (PMMA); depositing a protective coating on the photoresist layer, wherein the protective coating comprises a water-soluble polymeric material comprising a polyvinyl pyrrolidone (PVP); then exposing the workpiece to one or more fabrication processes; then removing the protective coating by at least partially dissolving the water-soluble polymeric material with a removal solution comprising water, which may be combined with the methods according to any one of Examples 21-36.

38. The method according to any one of Examples 21-37, wherein the PVP has an average molecular weight (MW) from about 20 kDa to about 100 kDa.

39. The method according to any one of Examples 21-38, wherein the workpiece comprising at least the substrate, the photoresist layer, and the protective coating is heated to a temperature in a range from about 80° C. to about 150° C. for about 1 minute to about 30 minutes prior to removing the protective coating.

40. The method according to any one of Examples 21-39, wherein the substrate comprises at least a first surface and a second surface, wherein the protective coating is disposed on the photoresist layer which is disposed on the first surface of the substrate, and wherein the one or more fabrication processes comprise exposing the second surface to a deposition process, an etch process, a cleaning process, a curing process, a thermal process, one or more other processes, or any combination thereof.

41. A workpiece, comprising: a photoresist layer disposed on a substrate, wherein the photoresist layer comprises a poly(methyl methacrylate) (PMMA); and a protective coating disposed on the photoresist layer, wherein the protective coating comprises a water-soluble polymeric material, and wherein the water-soluble polymeric material comprises a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

42. The workpiece according to Example 41, wherein the water-soluble polymeric material has an average molecular weight (MW) from about 1 kDa to about 1,500 kDa.

43. The workpiece according to Example 41 or 42, wherein the water-soluble polymeric material comprises the polyvinyl pyrrolidone (PVP).

44. The workpiece according to any one of Examples 41-43, wherein the PVP has an average molecular weight (MW) from about 20 kDa to about 100 kDa.

45. The workpiece according to any one of Examples 41-44, wherein the photoresist layer has a thickness in a range from about 100 nm to about 800 nm and the protective coating has a thickness in a range from about 100 nm to about 1,000 nm.

46. The workpiece according to any one of Examples 41-45, wherein the substrate comprises, consists of, or consist essentially of silicon.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications may be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation may be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method for protecting a photoresist on a workpiece, comprising:
depositing a photoresist layer on a first surface of a substrate, wherein the photoresist layer comprises a poly(methyl methacrylate) (PMMA);
depositing a protective coating on the photoresist layer disposed on the first surface, wherein the protective coating comprises a water-soluble polymeric material; then
exposing a second surface of the substrate to one or more fabrication processes, wherein the first surface is covered by the photoresist layer and the protective coating, and the second surface is uncovered; then
removing the protective coating by at least partially dissolving the water-soluble polymeric material with a removal solution comprising water, deionized water, an aqueous solution, isopropanol, methanol, ethanol, or any combination thereof.

2. The method of claim 1, wherein the water-soluble polymeric material comprises a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

3. The method of claim 1, wherein the water-soluble polymeric material has an average molecular weight (MW) from about 1 kDa to about 1,500 kDa.

4. The method of claim 1, wherein the water-soluble polymeric material comprises a polyvinyl pyrrolidone (PVP).

5. The method of claim 4, wherein the PVP has an average molecular weight (MW) from about 20 kDa to about 100 kDa.

6. The method of claim 1, wherein the water-soluble polymeric material is deposited on the photoresist layer by a spin-coating process to produce the protective coating.

7. The method of claim 1, wherein the workpiece comprising at least the substrate, the photoresist layer, and the protective coating is heated during a curing process to a temperature in a range from about 80° C. to about 150° C. for about 1 minute to about 30 minutes prior to removing the protective coating.

8. The method of claim 7, wherein the temperature is in a range from about 110° C. to about 130° C. for about 5 minutes to about 15 minutes during the curing process.

9. The method of claim 1, wherein the protective coating is removed from the photoresist layer during a removal process, the removal process comprises exposing the protective coating to sonication and the removal solution at a temperature in a range from about 20° C. to about 150° C. for about 1 minute to about 12 minutes while at least partially dissolving the water-soluble polymeric material.

10. The method of claim 1, wherein the removal solution consists essentially of water or deionized water.

11. The method of claim 1, wherein the one or more fabrication processes comprise exposing the second surface to a deposition process, an etch process, a cleaning process, a curing process, a thermal process, or any combination thereof.

12. A method for protecting a photoresist on a workpiece, comprising:
depositing a photoresist layer on a substrate, wherein the photoresist layer comprises a poly(methyl methacrylate) (PMMA);
depositing a protective coating on the photoresist layer, wherein the protective coating comprises a water-soluble polymeric material comprising a polyvinyl pyrrolidone (PVP); then
exposing the workpiece to one or more fabrication processes; then
removing the protective coating by at least partially dissolving the water-soluble polymeric material with a removal solution comprising water.

13. The method of claim 12, wherein the PVP has an average molecular weight (MW) from about 20 kDa to about 100 kDa.

14. The method of claim 12, wherein the workpiece comprising at least the substrate, the photoresist layer, and the protective coating is heated to a temperature in a range from about 80° C. to about 150° C. for about 1 minute to about 30 minutes prior to removing the protective coating.

15. The method of claim 12, wherein the substrate comprises at least a first surface and a second surface, wherein the protective coating is disposed on the photoresist layer which is disposed on the first surface of the substrate, and wherein the one or more fabrication processes comprise exposing the second surface to a deposition process, an etch process, a cleaning process, a curing process, a thermal process, or any combination thereof.

16. A workpiece, comprising:
a photoresist layer disposed on a substrate, wherein the photoresist layer comprises a poly(methyl methacrylate) (PMMA); and
a protective coating disposed on the photoresist layer, wherein the protective coating comprises a water-soluble polymeric material, and wherein the water-soluble polymeric material comprises a poly(acrylamide) (PAM), a polyvinyl pyrrolidone (PVP), a polyvinyl alcohol (PVA), a poly(acrylic acid) (PAA), a polyethylene oxide (PEO), a polyvinyl acetate (PVAc), salts thereof, derivatives thereof, or any combination thereof.

17. The workpiece of claim 16, wherein the water-soluble polymeric material has an average molecular weight (MW) from about 1 kDa to about 1,500 kDa.

18. The workpiece of claim 16, wherein the water-soluble polymeric material comprises the polyvinyl pyrrolidone (PVP).

19. The workpiece of claim 18, wherein the PVP has an average molecular weight (MW) from about 20 kDa to about 100 kDa.

20. The workpiece of claim 18, wherein the photoresist layer has a thickness in a range from about 100 nm to about 800 nm and the protective coating has a thickness in a range from about 100 nm to about 1,000 nm.
